(19) United States
(12) Patent Application Publication
(10) Pub. No.: US 2022/0192057 A1
(43) Pub. Date: Jun. 16, 2022

(54) LOCAL COOLING DEVICE AND LOCAL COOLING METHOD

(71) Applicant: NEC Corporation, Minato-ku, Tokyo (JP)

(72) Inventors: Koichi TODOROKI, Tokyo (JP); Minoru YOSHIKAWA, Tokyo (JP); Kunihiko ISHIHARA, Tokyo (JP); Masaki CHIBA, Tokyo (JP); Yoshinori MIYAMOTO, Tokyo (JP); Takafumi NATSUMEDA, Tokyo (JP); Nirmal Singh RAJPUT, Tokyo (JP)

(73) Assignee: NEC Corporation, Minato-ku, Tokyo (JP)

(21) Appl. No.: 17/603,111

(22) PCT Filed: Apr. 13, 2020
(86) PCT No.: PCT/JP2020/016282

§ 371 Date: Oct. 12, 2021

(30) Foreign Application Priority Data
Apr. 25, 2019 (JP) 2019-084385

(51) Int. Cl. H05K 7/20; G06F 1/20; H05K 7/14

(52) U.S. Cl. CPC H05K 7/20745; H05K 7/208; H05K 7/1497; G06F 1/20

(57) ABSTRACT

A local cooler includes: a housing formed into a box shape; a heat exchanger provided along a slope extending upward to a rear portion from a lower position located on the front side of the housing; a first intake/exhaust port provided on a front surface of the housing; a second intake/exhaust port provided on a bottom surface of the housing; third intake/exhaust ports provided at a plurality of locations among side surfaces, upper surface and rear surface of the housing; and a closing plate capable of selectively shielding these intake/exhaust ports.

### TECHNICAL FIELD

The present invention relates to a local cooling device (cooler) and a local cooling method capable of efficiently exchanging heat by eliminating the appearance of hot spots in a server room.

### BACKGROUND ART

In a server room installed in a data center or communication station building, the load of each accommodated server may vary. In such a server room, when the exhaust heat emitted from various parts of the server is uneven, a place called a hot spot where the air temperature is locally high is formed in the room.

For example, Patent Document 1 has been proposed as a technique for dealing with such a hot spot.

A cooling system 50 shown in Patent Document 1 is installed in a server room as shown in FIG. 7. In this server room, two rows of server rack rows 52 each composed of four server racks 51 are installed. A plurality of servers are stored in each server rack 51. Four local air conditioners 53 are arranged on an upper portion of each server rack 51 so as to face each other to constitute the cooling system 50.

These local air conditioners 53 exchange heat between a liquid refrigerant supplied to a refrigerant pipe 54 from a refrigerant device (not shown) and air a1 (warm air) taken in from an air inlet port 55 located at a rear portion and send out air a2 (cold air) cooled by the liquid refrigerant from an air outlet port 56 located at a front portion.

In such a cooling system 50, a low temperature space L is formed in a space between the server rack rows 52 by the air a2 (cold air) sent out from the air outlet port 56 of each local air conditioner 53.

By passing through the server rack 51, the air a2 (cold air) exchanges heat with a heat generating source in the server rack 51 and becomes the air a1 (warm air). This air a1 (warm air) forms a high temperature space H between the server rack row 52 and a shield such as a wall. The air a1 (warm air) in the high temperature space H is sucked in from the air inlet port 55 located at the rear portion of the local air conditioner 53.

Incidentally, in the cooling system shown in the above Patent Document 1, flows of warm air and cold air are limited, and in many cases, in order to set the cooling temperature of the local air conditioner 53 in accordance with a place where the air temperature is high, extra electrical power is required for operation, and the electrical power for cooling tends to increase.

As one method of reducing the electrical power for cooling, an attempt has been made to arrange a local cooler and carry out cooling according to each location.

For example, an air conditioner shown in Patent Document 2 can change the wind direction to front blowing or both side blowing by switching a blowout switching panel. Therefore, this air conditioner can adjust the temperature distribution of the room by changing the wind direction.

As a result, in the above-mentioned server room, it becomes possible to eliminate hot spots by flexibly arranging local coolers in response to changes in the positions of hot spot generation due to the ever-changing load of each server.

### PRIOR ART DOCUMENTS

### Patent Documents

[Patent Document 1] Japanese Unexamined Patent Application, First Publication No. 2013-221634

[Patent Document 2] Japanese Unexamined Patent Application, First Publication No. 2005-69652

### SUMMARY OF INVENTION

### Problems to be Solved by the Invention

However, Patent Document 2 only discloses a configuration in which the wind direction is changed to front blowing or both side blowing by switching the blowout switching panel. That is, Patent Document 2 does not disclose a specific configuration of how to change the wind direction in order to eliminate hot spots.

The present invention has been made in view of the above circumstances, and has an object of providing a local cooler and a local cooling method that can specifically and freely construct a flow path of air containing heat (warm air) or air after heat dissipation (cold air) in order to eliminate hot spots.

### Means for Solving the Problems

In order to solve the above problems, the present invention proposes the following means.

A local cooler according to a first aspect of the present invention includes: a housing formed into a box shape; a heat exchanger provided along a slope extending upward to a rear portion from a lower position located on the front side of the aforementioned housing; a first intake/exhaust port provided on a front surface of the aforementioned housing; a second intake/exhaust port provided on a bottom surface of the aforementioned housing; third intake/exhaust ports provided at a plurality of locations among side surfaces, upper surface and rear surface of the aforementioned housing; and a closing plate capable of selectively shielding the aforementioned first to third intake/exhaust ports.

In a local cooling method according to a second aspect of the present invention, while a heat exchanger is arranged along a slope extending upward to a rear portion from a lower position located on the front side of a housing, a first intake/exhaust port is provided on a front surface of the aforementioned housing, a second intake/exhaust port is provided on a bottom surface of the aforementioned housing, third intake/exhaust ports are provided at a plurality of locations among side surfaces, upper surface and rear surface of the aforementioned housing, and the aforementioned first to third intake/exhaust ports are selectively shielded by a closing plate.

### Advantageous Effects of the Invention

According to the present invention, the flow path of air containing heat (warm air) or the flow path of air after heat dissipation (cold air) can be freely changed, and it is possible to prevent hot spots having a high air temperature from appearing locally in the room beforehand.

### BRIEF DESCRIPTION OF DRAWINGS

FIG. 1 is a perspective view showing a configuration of a local cooler according to a first embodiment of the present invention.

FIG. 2 is a perspective view showing a configuration of a local cooler according to a second embodiment of the present invention.

FIG. 3 is a side view showing a configuration of a closing plate in the second embodiment.

FIG. 4A is a perspective view showing an air flow path of the local cooler according to the second embodiment.

FIG. 4B is a perspective view showing an air flow path of the local cooler according to the second embodiment.

FIG. 5 is a perspective view showing a configuration of a local cooler according to a third embodiment of the present invention.

FIG. 6 is a perspective view showing a configuration of a local cooler according to a fourth embodiment of the present invention.

FIG. 7 is a perspective view showing a conventional cooling system shown in Patent Document 1.

### EXAMPLE EMBODIMENTS

### First Embodiment

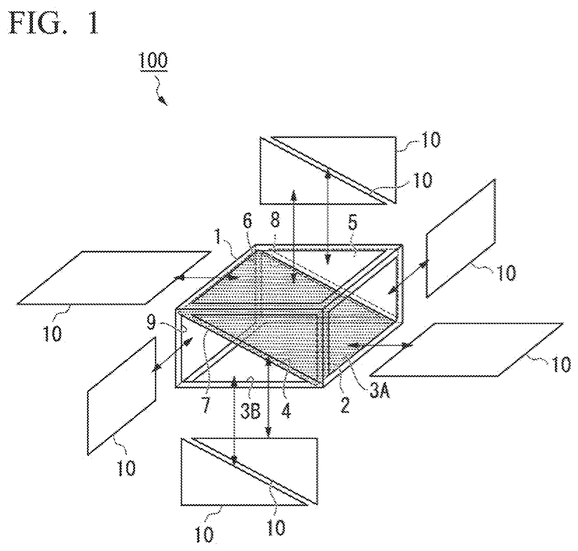

A local cooler 100 according to a first embodiment of the present invention will be described with reference to FIG. 1.

The local cooler 100 includes: a housing 1 formed into a box shape; a heat exchanger 2 inside the housing 1; a first intake/exhaust port 3A, a second intake/exhaust port 3B and third intake/exhaust ports 4 to 9 formed in the housing 1; and a closing plate capable of selectively shielding these intake/exhaust ports.

The heat exchanger 2 is provided along a slope extending upward to a rear portion from a lower position located on the front side of the housing 1.

The first intake/exhaust port 3A is an opening provided on a front surface of the housing 1, and cold air is mainly discharged through this opening.

The second intake/exhaust port 3B is an opening provided on a bottom surface of the housing 1, and warm air is mainly sucked in through this opening.

The third intake/exhaust ports 4 to 9 are openings provided on side surfaces, upper surface, and rear surface of the housing 1.

It should be noted that in the first embodiment, the third intake/exhaust ports 4 to 6 are provided at three places in an upper portion of the housing 1 with the heat exchanger 2 sandwiched therebetween, the third intake/exhaust ports 7 to 9 are provided at three places in a lower portion of the housing 1 with the heat exchanger 2 sandwiched therebetween, cold air is mainly discharged through the third intake/exhaust ports 4 to 6, and warm air is mainly sucked in through the third intake/exhaust ports 7 to 9. The positions and numbers of these intake/exhaust ports 4 to 9 can be freely determined.

The closing plate 10 is attached so that the first intake/exhaust port 3A, the second intake/exhaust port 3B and the third intake/exhaust ports 4 to 9 can be selectively shielded, and the warm air/cold air can be taken in or discharged from an optimal place by the attachment.

The local cooler 100 according to the first embodiment described above can take in air containing heat (warm air) into the housing 1 through the second intake/exhaust port 3B provided on the bottom surface of the housing 1 and/or the third intake/exhaust ports 7 to 9.

Thereafter, the air containing heat (warm air) taken into the housing 1 is dissipated and cooled by the heat exchanger 2 installed along the slope extending upward to the rear portion from the lower position located on the front side of the housing 1.

Furthermore, in the present embodiment, the air after heat dissipation (cold air) can be discharged to the outside through a plurality of first intake/exhaust ports 3A and/or the third intake/exhaust ports 4 to 6 provided on some of the front surface, the side surface and the upper surface of the housing 1.

At this time, in the present embodiment, by selectively shielding the first intake/exhaust port 3A, the second intake/exhaust port 3B and the third intake/exhaust ports 4 to 9 with the closing plate 10, the flow path of air containing heat (warm air) or air after heat dissipation (cold air) can be freely changed, and the appearance of hot spots having a high air temperature locally in the room can be prevented beforehand.

It should be noted that in the local cooler 100 according to the present embodiment, the second intake/exhaust port 3B and/or the third intake/exhaust ports 7 to 9 are mainly set as intake ports for sucking in air (warm air), and the first intake/exhaust port 3A and/or the third intake/exhaust ports 4 to 6 are set as exhaust ports for discharging air after heat dissipation (cold air). However, it is possible to freely set which port serves as an intake port/exhaust port.

### Second Embodiment

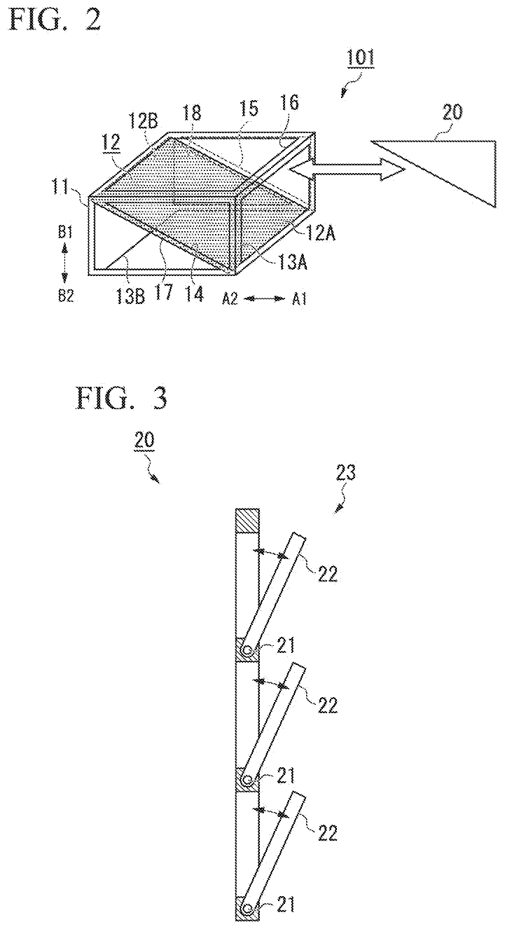

A local cooler 101 according to a second embodiment will be described with reference to FIGS. 2, 3, 4A and 4B.

The local cooler 101 includes: a housing 11 formed into a rectangular parallelepiped shape; a heat exchanger 12 inside the housing 11; a first intake/exhaust port 13A, a second intake/exhaust port 13B and third intake/exhaust ports 14 to 18 formed in the housing 11; and a closing plate 20 capable of selectively shielding these intake/exhaust ports.

It should be noted that in FIG. 2, the arrow A1 direction is defined as the front side, the arrow A2 direction is defined as the rear side, the arrow B1 direction is defined as the upper side, and the arrow B2 direction is defined as the lower side.

The local cooler 101 can be used in a space such as a server room where hot spots are likely to appear.

The heat exchanger 12 is provided in a square shape along a slope extending from a front end portion 12A located on the front side of the housing 11 to a rear end portion 12B, and a cooling pipe (not shown) through which a refrigerant flows is arranged inside or on a lower surface.

In the heat exchanger 12, the refrigerant flows from a lower portion toward an upper portion along the cooling pipe. Further, in the heat exchanger 12, the air to be cooled intersects and penetrates the slope, and the air moves along the slope to exchange heat with the refrigerant.

The first intake/exhaust port 13A is an opening provided above the heat exchanger 12 and on a front surface of the housing 11, and in this example, cold air is discharged through this opening.

The second intake/exhaust port 13B is an opening provided below the heat exchanger 12 and on a bottom surface of the housing 11, and in the present embodiment, warm air is sucked in through this opening.

The third intake/exhaust ports 14 to 16 are openings provided above the heat exchanger 12 and on both side surfaces and upper surface of the housing 11, and in the present embodiment, cold air cooled by the heat exchanger 12 is discharged through these openings.

The third intake/exhaust ports 17 and 18 are openings provided below the heat exchanger 12 and on both side surfaces of the housing 11, and in the present embodiment, warm air is sucked in through these openings.

That is, in the present embodiment, the intake/exhaust ports 14 to 16 are provided at three places in an upper portion of the housing 11 with the heat exchanger 12 sandwiched therebetween, and the intake/exhaust ports 17 and 18 are provided at two places in a lower portion of the housing 11 with the heat exchanger 12 sandwiched therebetween, respectively. On the other hand, no opening is formed on a rear surface of the housing 11.

The closing plate 20 is attached so that the first intake/exhaust port 13A, the second intake/exhaust port 13B and the third intake/exhaust ports 14 to 18 can be selectively shielded, and the flow path of air containing heat (warm air) or air after heat dissipation (cold air) can be freely changed by the selective attachment. It should be noted that the closing plate 20 may be configured by a plate-like body that can be fitted into groove portions formed in peripheral edge portions of the openings of the first intake/exhaust port 13A, the second intake/exhaust port 13B and the third intake/exhaust ports 14 to 18 (see FIG. 2).

Further, the closing plate 20 may be configured as a louver 23 that rotatably supports a plurality of plate-like bodies 22 via shaft bodies 21 arranged so as to cross the opening peripheral edge portion or the opening as shown in FIG. 3.

At this time, the louver 23 may operate the plate-like bodies 22 individually, or may collectively open and close the plurality of plate-like bodies 22 in units of openings by connecting links.

The local cooler 101 according to the second embodiment described above can take in air containing heat (warm air) into the housing 11 through the second intake/exhaust port 13B provided on the bottom surface of the housing 11 and/or the third intake/exhaust ports 17 and 18 below the heat exchanger 12.

Thereafter, the air containing heat (warm air) taken into the housing 11 is dissipated and cooled by the heat exchanger 12 installed along the slope extending upward to the rear portion from the lower position located on the front side of the housing 11.

Furthermore, the above local cooler 101 can discharge the air after heat dissipation (cold air) to the outside through a plurality of first intake/exhaust ports 13A and/or the third intake/exhaust ports 14 to 16 provided on some of the front surface, the side surface, the upper surface and the rear surface of the housing 11.

At this time, the above local cooler 101 can selectively shield the first intake/exhaust port 13A, the second intake/exhaust port 13B and the third intake/exhaust ports 14 to 18 by the closing plate 20. Therefore, the local cooler 101 can freely change the flow path of air to be sucked in (warm air) or air after heat dissipation (cold air), and it is possible to prevent hot spots having a high air temperature from appearing locally in the room beforehand.

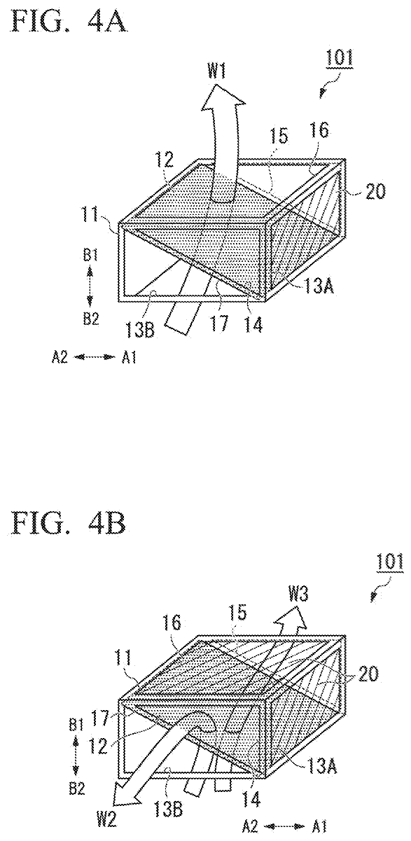

As an example, as shown in FIG. 4A, the above local cooler 101 can take in air (warm air) into the housing 11 through the second intake/exhaust port 13B below the heat exchanger 12 by closing the first intake/exhaust port 13A on the front surface of the heat exchanger 12 with the closing plate 20. Thereafter, the air taken in through the second intake/exhaust port 13B moves from the lower portion toward the upper portion due to the upward flow of warm air. At that time, the air is cooled by passing through the heat exchanger 12 and then discharged from the intake/exhaust ports 14 to 16 (in FIG. 4A, an air flow W1 discharged from the intake/exhaust port 16 is shown).

Furthermore, as shown in FIG. 4B, the above local cooler 101 can additionally provide the closing plate 20 that closes the first intake/exhaust port 13A and also closes the intake/exhaust port 16 located on the upper surface of the housing 11. In this case, the local cooler 101 can discharge the air (cold air) cooled by passing through the heat exchanger 12 in the housing 11 from the intake/exhaust ports 14 and 15 above the heat exchanger 12 and on both sides of the housing 11 (shown as air flows W2 and W3 in FIG. 4B).

It should be noted that the air flows W2 and W3 at this time are curved by 90° after passing through the heat exchanger 12, and are discharged from the intake/exhaust ports 14 and 15 on both sides of the housing 11.

In the local cooler 101 as described above, by allowing various air flows to be determined later, the degree of freedom in installing the local cooler can be increased, and hot spots can be eliminated under various situations.

Furthermore, the above local cooler 101 is not limited to a closing pattern of the closing plate 20 shown in FIGS. 4A and 4B, and the air taken in through the first intake/exhaust port 13A may be discharged from the second intake/exhaust port 13B after cooling, in a state where only the intake/exhaust port 16 located on the upper surface of the housing 11 is closed.

That is, in the above local cooler 101, the second intake/exhaust port 13B located on the lower surface of the housing 11 may function as an exhaust port, and it becomes possible to form various air flow paths depending on the situation.

### Third Embodiment

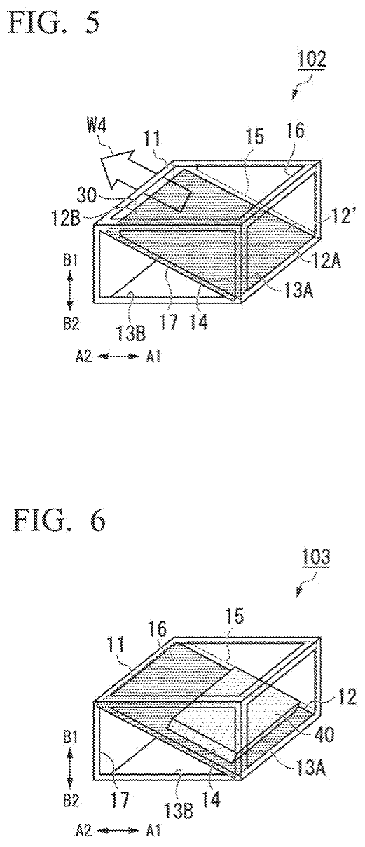

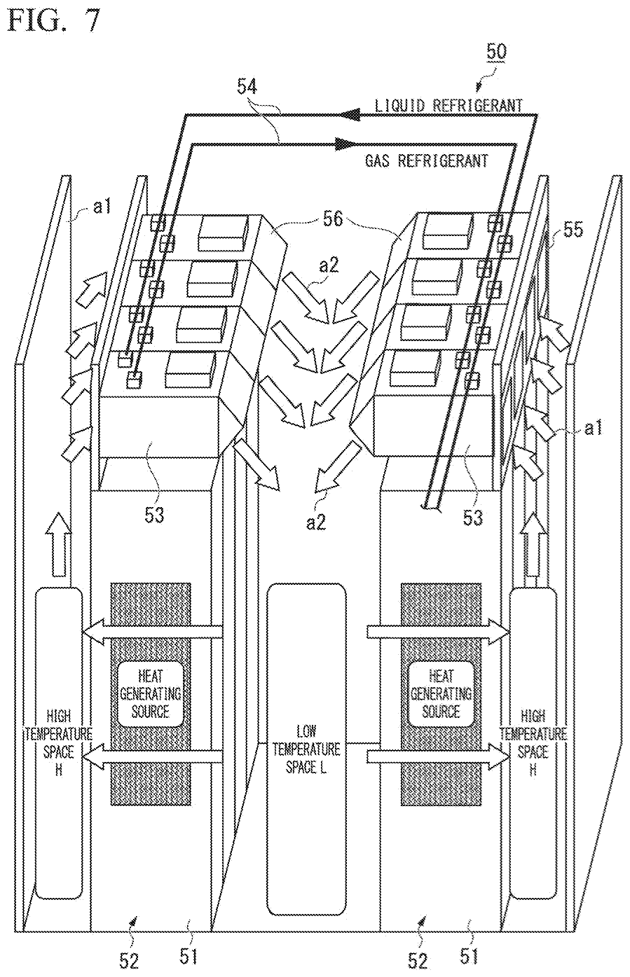

A third embodiment of the present invention will be described with reference to FIG. 5.

A local cooler 102 shown in the third embodiment differs in configuration from the local cooler 101 shown in the second embodiment in the installation position of a heat exchanger 12′.

In the heat exchanger 12′ shown in the third embodiment, a slope extending from the front end portion 12A located on the front side of the housing 11 to the rear end portion 12B is formed, and the rear end portion 12B of the heat exchanger 12′ is arranged at an intermediate position on the rear surface of the housing 11 so as to have a distance from the upper surface of the housing 11.

That is, the gradient of the heat exchanger 12′ shown in the third embodiment is moderately set as compared with the heat exchanger 12 shown in the second embodiment.

In the above local cooler 102, a rear exhaust port 30 is formed above the rear end portion 12B of the heat exchanger 12′ and at the upper position of the rear surface of the housing 11.

As a result, the above local cooler 102 enables the air that has risen so as to slide on the upper surface of the heat exchanger 12′ through the rear exhaust port 30 provided in the upper portion of the rear surface of the housing 11 to travel as it is in a straight line without changing the flow path horizontally, which is denoted by a reference numeral W4.

That is, the above local cooler 102 can advance the air sucked in from the first intake/exhaust port 13A as it is and discharge from the rear exhaust port 30 on the rear surface of the housing without applying resistance thereto.

Further, when the third intake/exhaust ports 14 to 18 are closed, the above local cooler 102 can also discharge the air that had passed through the heat exchanger 12 from the rear exhaust port 30 without curving it by 90°.

As a result, the above local cooler 102 can flexibly determine the air flow direction while suppressing a decrease in the cooling capacity due to the bending direction of the air flow path and maintaining the cooling capacity.

### Fourth Embodiment

A fourth embodiment of the present invention will be described with reference to FIG. 6.

A local cooler 103 shown in the fourth embodiment differs in configuration from the local coolers 101 and 102 shown in the second and third embodiments in that an air blower 40 for sending air sucked in from the second intake/exhaust port 13B is provided on an inclined surface of the heat exchanger 12.

This air blower 40 is located on the upper surface side of the heat exchanger 12 and below the center (intake/exhaust port 13A side) and has a role in maintaining the cooling performance even if the air flow direction changes.

More specifically, although the cooling capacity of the heat exchanger 12 is determined by the area where the phase change occurs in the device, in order to increase the cooling capacity, it is important to shorten the time period until the liquid refrigerant is heated by the sensible heat after flowing into the cooling pipe in the device and the phase change occurs.

For this reason, in the present embodiment, the air blower 40 for promptly changing the phase of the refrigerant is installed to increase the cooling efficiency of the heat exchanger 12.

It should be noted that the above air blower 40 may employ a centrifugal fan or an axial flow fan, and its form is not limited.

Further, the first to fourth embodiments described above may be combined with each other, and an appropriate combination can be made in accordance with the type of usage of the user.

Although the embodiments of the present invention have been described above in detail with reference to the drawings, the specific configurations are not limited to these embodiments and include any design changes and the like without departing from the spirit and scope of the present invention.

Priority is claimed on Japanese Patent Application No. 2019-084385, filed Apr. 25, 2019, the content of which is incorporated herein by reference.

### INDUSTRIAL APPLICABILITY

The present invention can be applied to a local cooler and a local cooling method capable of efficiently exchanging heat by eliminating the appearance of hot spots in a server room.

### REFERENCE SIGNS LIST

1 Housing
2 Heat exchanger
3A First intake/exhaust port
3B Second intake/exhaust port
4 Intake/exhaust port
5 Intake/exhaust port
6 Intake/exhaust port
7 Intake/exhaust port
8 Intake/exhaust port
9 Intake/exhaust port
10 Closing plate
11 Housing
12 Heat exchanger
12′ Heat exchanger
13A First intake/exhaust port
13B Second intake/exhaust port
14 Intake/exhaust port
15 Intake/exhaust port
16 Intake/exhaust port
17 Intake/exhaust port
18 Intake/exhaust port
20 Closing plate
30 Rear exhaust port
40 Air blower
100 Local cooler
101 Local cooler
102 Local cooler
103 Local cooler

What is claimed is:

1. A local cooler comprising:
a housing formed into a box shape;
a heat exchanger provided along a slope extending upward to a rear portion from a lower position located on a front side of said housing;
a first intake/exhaust port provided on a front surface of said housing;
a second intake/exhaust port provided on a bottom surface of said housing;
third intake/exhaust ports provided at a plurality of locations among side surfaces, upper surface and rear surface of said housing; and
a closing plate capable of selectively shielding said first to third intake/exhaust ports.

2. The local cooler according to claim 1,
wherein said second intake/exhaust port and the third intake/exhaust ports located below said heat exchanger are openings for air intake, and
said first intake/exhaust port and the third intake/exhaust ports located above said heat exchanger are openings for air exhaust.

3. The local cooler according to claim 2, wherein said closing plate is installed on either one side of said first intake/exhaust port and the second intake/exhaust port in order to adjust an overall air flow.

4. The local cooler according to claim 3, wherein said closing plate is further installed in any of said third intake/exhaust ports in order to adjust the overall air flow.

5. The local cooler according to any one of claim 1, wherein a louver having a blade that is rotatable around a mounting shaft facing a direction across an air flow is installed as said closing plate.

6. The local cooling according to claim 1,
wherein said housing is formed into a rectangular parallelepiped shape, and
said third intake/exhaust port located on the side surface of said housing is formed into a triangular shape by said heat exchanger provided along said slope.

7. The local cooling according to claim 1,
wherein a rear end portion of said heat exchanger is arranged on the rear surface of said housing so as to have a distance from the upper surface of said housing, and
two rear openings are formed as said third intake/exhaust ports at upper and lower positions of the rear surface of said housing with the rear end portion of said heat exchanger sandwiched therebetween.

8. The local cooler according to claim 1, wherein the heat exchanger located on the slope in said housing is provided with an air blower for sending air sucked in from any of said first to third intake/exhaust ports.

9. A local cooling method comprising:
arranging a heat exchanger along a slope extending upward to a rear portion from a lower position located on a front side of a housing;
providing a first intake/exhaust port on a front surface of said housing and a second intake/exhaust port on a bottom surface of said housing, respectively;
providing third intake/exhaust ports at a plurality of locations among side surfaces, upper surface and rear surface of said housing; and
selectively shielding said first to third intake/exhaust ports by a closing plate.

10. The local cooling method according to claim 9,
wherein said second intake/exhaust port and the third intake/exhaust ports located below said heat exchanger are openings for air intake, and
said first intake/exhaust port and the third intake/exhaust ports located above said heat exchanger are openings for air exhaust.
